(19) United States
(12) Patent Application Publication
(10) Pub. No.: US 2009/0260382 A1
(43) Pub. Date: Oct. 22, 2009

(54) ELECTRIC EQUIPMENT ASSEMBLY, AND OUTDOOR UNIT OF AIR CONDITIONER AND AIR CONDITIONER PROVIDED WITH THE SAME

(75) Inventors: Hisashi Takeichi, Osaka (JP); Naohiro Kawaski, Osaka (JP)

Correspondence Address: GLOBAL IP COUNSELORS, LLP, 1233 20TH STREET, NW, SUITE 700, WASHINGTON, DC, 20036-2680, US

(73) Assignee: DAIKIN INDUSTRIES, LTD., Osaka-shi, Osaka (JP)

(21) Appl. No.: 12/090,995

(22) PCT Filed: Nov. 6, 2006
(86) PCT No.: PCT/JP2006/322071

§ 371 Date: Apr. 21, 2008

(30) Foreign Application Priority Data
Nov. 7, 2005 (JP) 2005-322250

(51) Int. Cl. F25D 23/00; H05K 5/00

(52) U.S. Cl. 62/259.1; 361/752

(57) ABSTRACT

An electric equipment assembly has a frame with various electric components attached to the frame. The electric components include a control circuit board mounted with operating control elements and an inverter control element. Preferably the electric equipment assembly is disposed in outdoor units of an air conditioner. Each outdoor unit includes a structure in which the inside of a casing has a generally rectangular parallelepiped box shape divided into a fan chamber and a machine chamber by a partition plate extending vertically. The frame is provided such that a substrate surface of the control circuit board is positioned along a partition plate and is also inclined to a front side of the unit casing, with the frame provided in a unit casing so that an increase in airflow resistance in a fan chamber is prevented and the on-site workability is ensured at the same time.

### TECHNICAL FIELD

The present invention relates to an electric equipment assembly, and an outdoor unit of an air conditioner and an air conditioner provided with the same. More specifically, in an outdoor unit of an air conditioner having a structure in which the inside of a casing having a generally rectangular parallelepiped box shape is divided into a fan chamber and a machine chamber by a partition plate extending vertically, the present invention relates to an electric equipment assembly disposed in the machine chamber, and to an outdoor unit of an air conditioner and an air conditioner provided with the same.

### BACKGROUND ART

As a conventional outdoor unit of an air conditioner, there is known an outdoor unit having a structure in which the inside of a casing having a generally rectangular parallelepiped box shape is divided into a fan chamber and a machine chamber by a partition plate extending vertically. This fan chamber mainly includes an outdoor heat exchanger and an outdoor fan disposed therein. In addition, the machine chamber mainly includes a compressor, refrigerant circuit components comprising valves, refrigerant pipes, and the like, and an electric equipment assembly disposed therein. This type of electric equipment assembly is configured such that a control circuit board mounted with an operating control element and an inverter control element that requires cooling during operation (for example, power transistor, diode, etc.) are attached to a frame having a generally rectangular shape in a plan view of the casing. The frame of this electric equipment assembly is disposed such that a substrate surface of the control circuit board is perpendicular to a front side of the casing (in other words, in parallel to a lateral side of the casing) (see patent document 1).

Patent Document 1

Japanese Patent Application Publication No. H09-236284

### DISCLOSURE OF THE INVENTION

However, in the above described electric equipment assembly, although it is ideal that the frame is formed in a generally rectangular shape in a plan view of the frame in terms of reduction in the size of the electric equipment assembly, the following problems arise: part of the frame other than a cooling fin that constitutes the electric equipment assembly protrudes into the fan chamber, causing an increase in airflow resistance in the fan chamber to easily occur; and the on-site workability during maintenance and the like is difficult to ensure when a plurality of outdoor units each provided with this type of electric equipment assembly are juxtaposed to each other.

An object of the present invention is, in an outdoor unit of an air conditioner having a structure in which the inside of a casing having a generally rectangular parallelepiped box shape is divided into a fan chamber and a machine chamber by a partition plate extending vertically, to prevent an increase in airflow resistance in the fan chamber and ensure on-site workability at the same time.

An electric equipment assembly according to a first aspect of the present invention is an electric equipment assembly disposed in a machine chamber of an outdoor unit of an air conditioner having a structure in which an inside of a casing having a generally rectangular parallelepiped box shape is divided into a fan chamber and the machine chamber by a partition plate extending vertically, wherein various electric components including control circuit board mounted with operating control elements and an inverter control element are attached to the electric equipment assembly, and the electric equipment assembly comprises a frame provided such that a substrate surface of the control circuit board is positioned along the partition plate and is also inclined to a front side of the casing, with the frame provided in the casing.

With this electric equipment assembly, the frame is provided in the casing such that a substrate surface of the control circuit board is positioned along the partition plate and is also inclined to the front side of the casing, thus it is possible to prevent part of the frame from protruding into the fan chamber and also to perform maintenance and the like of the control circuit board even when a plurality of outdoor units each provided with this type of electric equipment assembly are juxtaposed to each other. Accordingly, with this electric equipment assembly, it is possible to prevent an increase in airflow resistance in the fan chamber and ensure on-site workability at the same time.

An electric equipment assembly according to a second aspect of the present invention is the electric equipment assembly according to the first aspect of the present invention, wherein the frame has a generally rectangular shape in a plan view of the casing, and a corner of the frame on the partition plate side is in contact with the partition plate so as to be positioned along a bent surface of the partition plate.

With this electric equipment assembly, the corner of the frame on the partition plate side is in contact with the partition plate so as to be positioned along the bent surface of the partition plate, thus the corner of the frame does not protrude into the fan chamber. Accordingly, it is possible to reliably prevent an increase in airflow resistance in the fan chamber.

An electric equipment assembly according to a third aspect of the present invention is the electric equipment assembly according to either the first or the second aspect of the present invention, wherein a highly frequently accessed control element among various operating control elements is disposed closer to the front side of the casing.

With this electric equipment assembly, the highly frequently accessed control element are disposed closer to the front side of the casing, thus it is possible to improve visibility and serviceability of the highly frequently accessed control element.

An electric equipment assembly according to a fourth aspect of the present invention is the electric equipment assembly according to the third aspect of the present invention, wherein the frame is inclined to the front side of the casing such that the entirety of the highly frequently accessed control element is visible, without being hidden by the lateral side of the casing even when the frame is viewed in a direction perpendicular to the substrate surface.

With this electric equipment assembly, even when a plurality of outdoor units each provided with such an electric equipment assembly are juxtaposed to each other, it is possible to maintain visibility and serviceability of the highly frequently accessed control element in good condition and further improve on-site workability.

An electric equipment assembly according to a fifth aspect of the present invention is the electric equipment assembly according to the third or the fourth aspect of the present invention, wherein the frame includes a substrate attachment plate disposed along the partition plate and a substrate protection plate that covers the substrate attachment plate from a side opposite the partition plate. The outer surface of the substrate protection plate has an auxiliary circuit board attached thereto, which is different from the control circuit board and mounted with the highly frequently accessed control element.

With this electric equipment assembly, the auxiliary circuit board different from the control circuit board and mounted with the highly frequently accessed control elements is attached to the outer surface of the substrate protection plate, thus further improving visibility and serviceability of the highly frequently accessed control element.

An outdoor unit of an air conditioner according to a sixth aspect of the present invention comprises a casing having a generally rectangular parallelepiped box shape, a partition plate extending vertically so as to divide the inside of the casing into a fan chamber and a machine chamber, and the electric equipment assembly according to any one of the first to the fifth aspects of the present invention, which is disposed in the machine chamber.

This outdoor unit of the air conditioner is provided with the electric equipment assembly according to any one of the first to the fifth aspects of the present invention, thus it is possible to prevent an increase in airflow resistance in the fan chamber and ensure on-site workability at the same time.

An air conditioner according to a seventh aspect of the present invention comprises a first outdoor unit and second outdoor unit. The first outdoor unit comprises the outdoor unit of the air conditioner according to the sixth aspect of the present invention. The second outdoor unit is laterally juxtaposed to the first outdoor unit and comprises the outdoor unit of the air conditioner according to the sixth aspect of the present invention, and the casing thereof has a different height from the casing of the first outdoor unit. In addition, the frame of the electric equipment assembly of the first outdoor unit and the frame of the electric equipment assembly of the second outdoor unit are disposed at the same height above the installation surface of each casing.

With this air conditioner, when two outdoor units are laterally juxtaposed to each other, the units are disposed in their respective casings such that the electric equipment assembly of each outdoor unit is located at the same height. Therefore, operators will have access to each electric equipment assembly in the same position. Accordingly, even when a plurality of outdoor units each having a casing with a different height are laterally juxtaposed to each other, it is possible to improve on-site workability.

### BRIEF DESCRIPTION OF THE DRAWINGS

FIG. 1 is a plan view of an outdoor unit in which an embodiment of an electric equipment assembly according to the present invention is adopted (shown with a top plate and refrigerant circuit components other than a compressor, an outdoor heat exchanger, and shut-off valves removed).

FIG. 2 is an elevation view of the outdoor unit (with left and right front plates and refrigerant circuit components other than the compressor, the outdoor heat exchanger, and the shut-off valves removed).

FIG. 3 is a view of the electric equipment assembly provided in a machine chamber viewed from the bottom.

FIG. 4 is a view of the electric equipment assembly provided in the machine chamber, viewed in a direction A in FIG. 1.

FIG. 5 is a view of the electric equipment assembly provided in the machine chamber, viewed in a direction B in FIG. 1.

FIG. 6 is a view of a state in which a partition plate is removed from FIG. 5.

FIG. 7 is an elevation view of an outdoor unit according to an alternative embodiment (with left and right front plates and refrigerant circuit components other than a compressor, an outdoor heat exchanger, and shut-off valves removed).

FIG. 8 is a view of two juxtaposed outdoor units each having a casing with a different height.

### DESCRIPTION OF THE REFERENCE SYMBOLS

1, 101 outdoor unit
2, 102 unit casing
7 electric equipment assembly
28, 128 partition plate
71 frame
72 substrate attachment plate
76 substrate protection plate
91 control circuit board
98 first auxiliary circuit board
98a, 98b highly frequently accessed control element
S1 fan chamber
S2 machine chamber

### BEST MODE FOR CARRYING OUT THE INVENTION

An embodiment of an electric equipment assembly, and an outdoor unit of an air conditioner and an air conditioner provided with the electric equipment assembly according to the present invention is now described with reference to the drawings.

### (1) Entire Structure of the Outdoor Unit

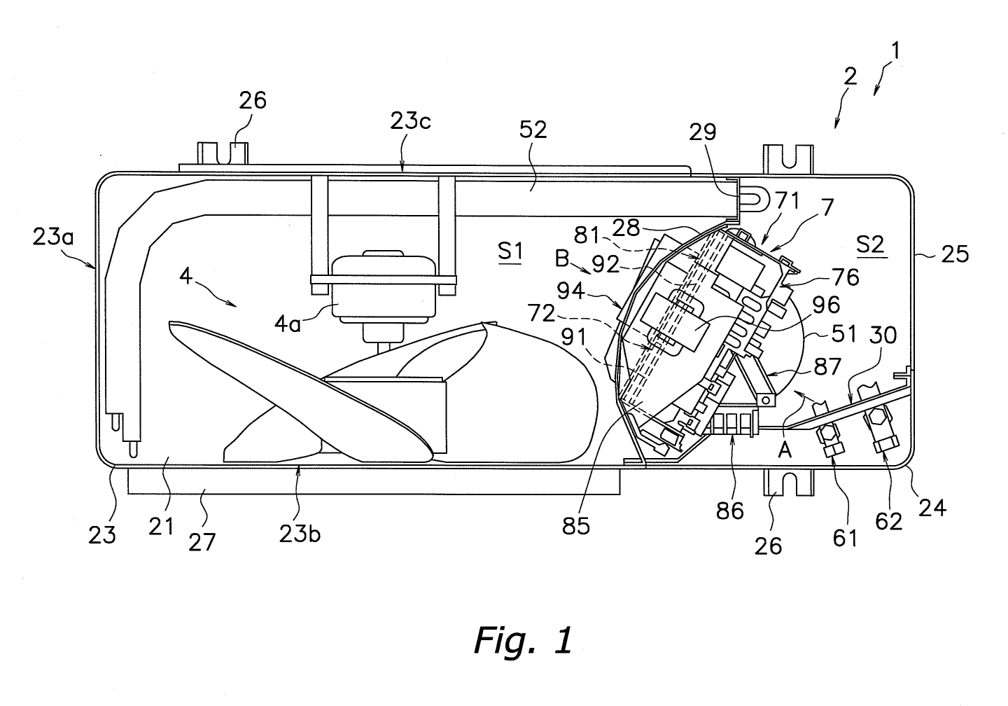

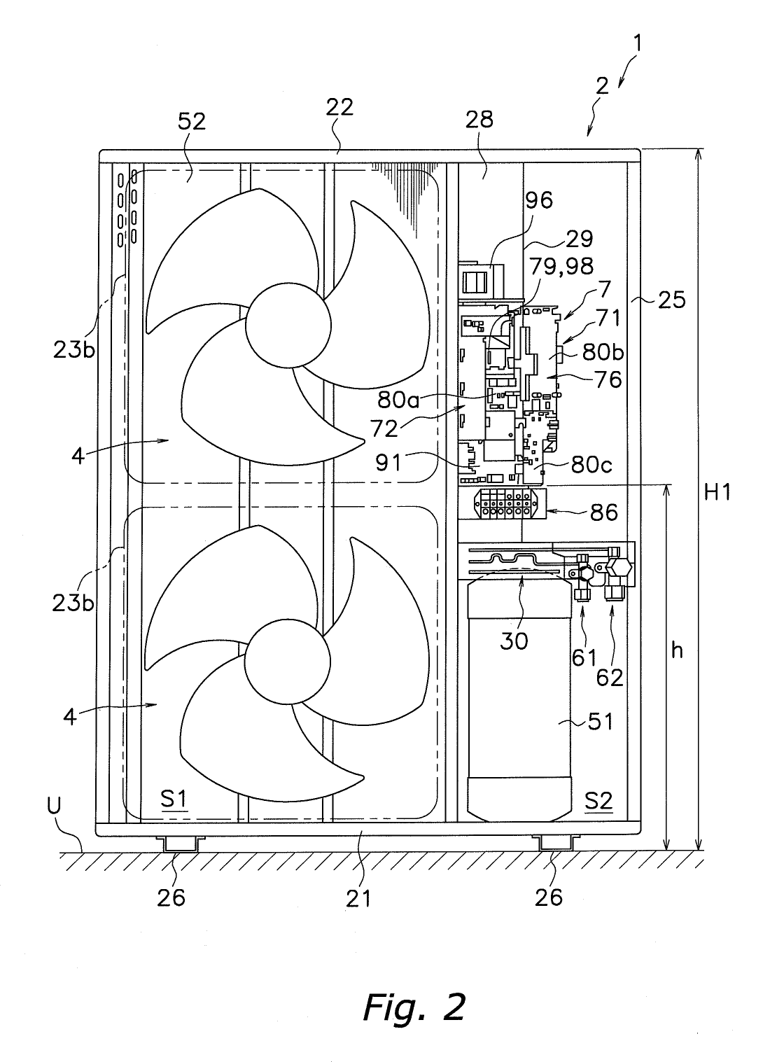

FIG. 1 is a plan view of an outdoor unit 1 in which an embodiment of the electric equipment assembly according to the present invention is adopted (shown with a top plate 22 and refrigerant circuit components 5 other than a compressor 51, an outdoor heat exchanger 52, and shut-off valves 61, 62 removed). In addition, FIG. 2 is an elevation view of the outdoor unit 1 (with left and right front plates 23, 24 and the refrigerant circuit components 5 other than the compressor 51, the outdoor heat exchanger 52, and the shut-off valves 61, 62 removed).

This outdoor unit 1 is installed outside, and has a so-called trunk structure in which the inside of a generally rectangular parallelepiped box shaped unit casing 2 is divided into a fan chamber S1 and a machine chamber S2 by a partition plate 28 extending vertically. This outdoor unit 1 is connected to an indoor unit (not shown) placed in an air-conditioned room via a refrigerant pipe (not shown). The outdoor unit 1 mainly comprises: the unit casing 2 having a generally rectangular parallelepiped box shape; outdoor fans 4; the refrigerant circuit components 5 including devices such as the compressor 51 and the outdoor heat exchanger 52, valves such as the liquid side shut-off valve 61 and the gas side shut-off valve 62, and members such as pipes so as to constitute a refrigerant circuit; and an electric equipment assembly 7 configured to control the operation of the outdoor unit 1. Note that in the description below, unless otherwise specified particularly, terms such as “up,” “down,” “left,” “right,” “front”, “back,” “front side,” and “rear side” indicate the directions when the outdoor unit 1 shown in FIG. 2 is viewed from the front side thereof.

### (2) Structure of the Unit Casing

The unit casing 2 mainly comprises a base plate 21, the top plate 22, the left front plate 23, the right front plate 24, and a right side plate 25.

The base plate 21 is a metallic plate-like member having a horizontally long and generally rectangular shape, which constitutes a base portion of the unit casing 2. The peripheral portion of the base plate 21 is bent upwardly. The outer surface of the base plate 21 is provided with two stationary legs 26 that are fixed on the installation surface at work site. Each of the stationary legs 26 has a generally U-shape in a front view of the unit casing 2, and is a metallic plate-like member which extends from the front side of the unit casing 2 to the rear side thereof.

The top plate 22 is a metallic plate-like member having a horizontally long and generally rectangular shape, which constitutes a top portion of the outdoor unit 1.

The left front plate 23 is a metallic plate-like member that mainly constitutes a left portion of the front side and a left side portion of the unit casing 2, and the lower portion of the left front plate 23 is fixed to the base plate 21 by a screw or the like. The left front plate 23 has an intake port 23a formed therein for air to be drawn into the unit casing 2 by the outdoor fans 4. In addition, the left front plate 23 is provided with discharge ports 23b for blowing out the air drawn inside from the rear side and the left side of the unit casing 2 by the outdoor fans 4. There are two discharge ports 23b formed above and below, each having a fan grille 27 provided thereto.

The right front plate 24 is a metallic plate-like member that mainly constitutes a right portion of the front side and a front portion of the right side of the unit casing 2, and the lower portion of the right front plate 24 is fixed to the base plate 21 by a screw or the like. In addition, the left end portion of the right front plate 24 is fixed to the right end portion of the left front plate 23 by a screw or the like.

The right side plate 25 is a metallic plate-like member that mainly constitutes a rear portion of the right side and a right rear side portion of the unit casing 2, and the lower portion of the right side plate 25 is fixed to the base plate 21 by a screw or the like. Between the back end portion of the left front plate 23 and the rear side end portion of the right side plate 25 in the horizontal direction, there is formed an intake port 23c for air to be drawn into the unit casing 2 by the outdoor fans 4.

Inside this type of unit casing 2 is provided with the partition plate 28 and a tube sheet 29. The partition plate 28 is a vertically extending metallic plate-like member disposed on the base plate 21, and the partition plate 28 is disposed so as to divide the inside of the unit casing 2 into two spaces, i.e., a left space and a right space. In this embodiment, the partition plate 28 has a bent shape so as to protrude toward the fan chamber S1 in a plan view of the unit casing 2. The tube sheet 29 is a metallic plate-like member provided so as to face the right end side of the outdoor heat exchanger 52 having a generally L-shape and disposed so as to extend along the unit casing 2 from the left side to the rear side thereof, and the lower portion of the tube sheet 29 is fixed to the base plate 21 by a screw or the like. The end portion of the tube sheet 29 on the front side of the unit casing 2 and the end portion of the partition plate 28 on the rear side of the unit casing 2 are fixed to each other by a screw or the like. In addition, the right end portion of the left front plate 23 is fixed to the partition plate 28 at the front end portion thereof by a screw or the like. The end portion on the rear side of the right side plate 25 is fixed to the tube sheet 29 at the end portion thereof on the rear side of the unit casing 2 by a screw or the like.

In this way, the inside of the unit casing 2 is divided into the fan chamber S1 and a machine chamber S2 by the partition plate 28. More specifically, the fan chamber S1 is a space surrounded by the base plate 21, the top plate 22, the left front plate 23, and the partition plate 28, and mainly the outdoor fans 4 and the outdoor heat exchanger 52 are disposed therein. The machine chamber S2 is a space surrounded by the base plate 21, the top plate 22, the right front plate 24, the right side plate 25, and the partition plate 28, and mainly the electric equipment assembly 7 and the refrigerant circuit components 5 other than the outdoor heat exchanger 52 are disposed therein. The unit casing 2 is configured such that the inside of the machine chamber S2 will be exposed by removing the right front plate 24. In other words, the right front plate 24 is removed when working on site to perform maintenance and the like of the refrigerant circuit components 5 and the electric equipment assembly 7 housed in the machine chamber S2 of the outdoor unit 1.

### (3) Structure of the Outdoor Fan

Each of the outdoor fans 4 is a propeller fan having a plurality of blades and is disposed on the front side of the outdoor heat exchanger 52 in the fan chamber S1. In this embodiment, two outdoor fans 4 are disposed above and below in the fan chamber S1 so as to face the discharge ports 23b. Each of these outdoor fans 4 is configured to be rotatably driven by an outdoor fan electric motor 4a. When the outdoor fans 4 are driven, air is drawn into the inside of the unit casing 2 through the intake ports 23a, 23c on the rear side and the left side of the unit casing 2. After the air passes through the outdoor heat exchanger 52, the air is blown out to the outside of the unit casing 2 from the discharge ports 23b on the front side of the unit casing 2.

### (4) Structure of the Refrigerant Circuit Component

The compressor 51 is a hermetic compressor that houses a compressor electric motor in the housing, and is disposed in the machine chamber S2. Here, the compressor electric motor is a so-called inverter driven electric motor in which the frequency can be controlled by the electric equipment assembly 7. In this embodiment, the compressor 51 has a longitudinal cylinder shape whose height is about ⅓ to ½ of the overall height of the unit casing 2, and a lower portion of the compressor 51 is fixed to the base plate 21. In addition, in a plan view of the unit casing 2, the compressor 51 is disposed near in the center of the machine chamber S2 in the front and back direction and also near the partition plate 28 of the machine chamber S2.

The outdoor heat exchanger 52 is disposed in the fan chamber S1. Through the outdoor heat exchanger 52, heat exchange is performed with the air that is drawn into the unit casing 2 by the outdoor fans 4. The outdoor heat exchanger 52 has a generally L-shape in a plan view of the unit casing 2, and is disposed so as to extend along the unit casing 2 from the left side to the rear side thereof.

Inside the unit casing 2, the liquid side shut-off valve 61 and the gas side shut-off valve 62 are disposed, to which refrigerant pipes on the indoor unit side are connected. More specifically, the liquid side shut-off valve 61 and the gas side shut-off valve 62 are disposed at a position facing the right front plate 24 at the front portion of the machine chamber S2. In this embodiment, the liquid side shut-off valve 61 and the gas side shut-off valve 62 are supported by an elongated plate shaped shut-off support member 30 provided so as to extend between the right end portion of the left front plate 23 and the front end portion of the right side plate 25. The shut-off support member 30 is disposed at a height near the upper end of the compressor 51 in the machine chamber S2.

### (5) Structure of the Electric Equipment Assembly

The electric equipment assembly 7 includes various electric components such as a control circuit board 91 mounted with the operating control element for controlling operation and the inverter control element 92. In this embodiment, the electric equipment assembly 7 is disposed near the partition plate 28 at the upper portion in the machine chamber S2. The electric equipment assembly 7 mainly includes a frame 71, a terminal block 86, and a terminal block support member 87.

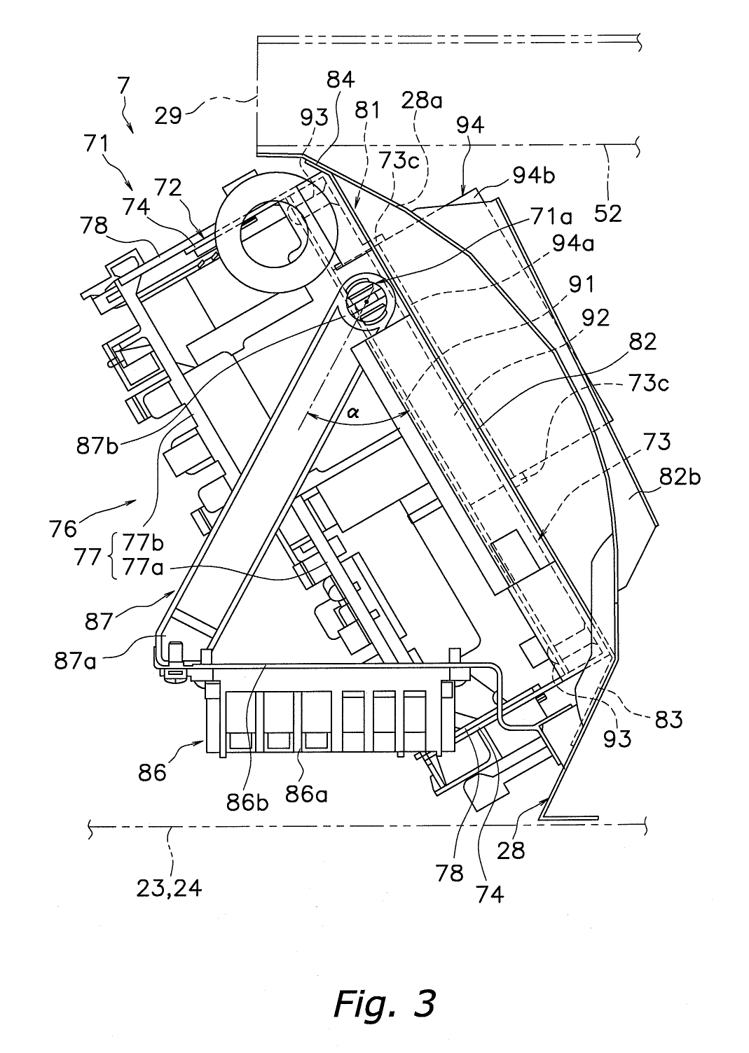

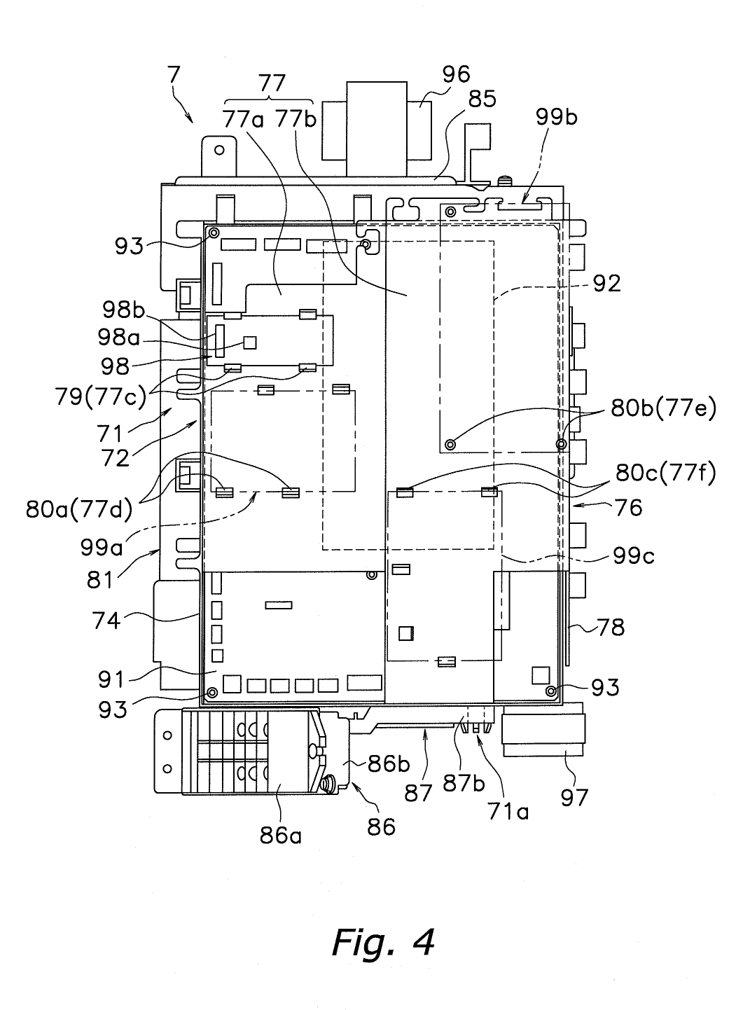

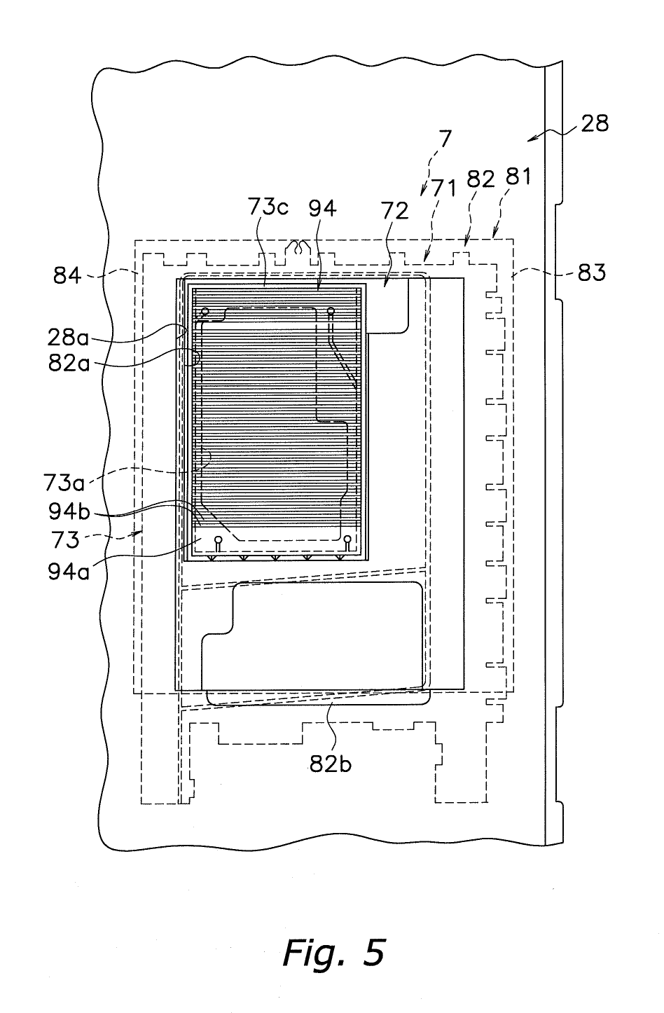

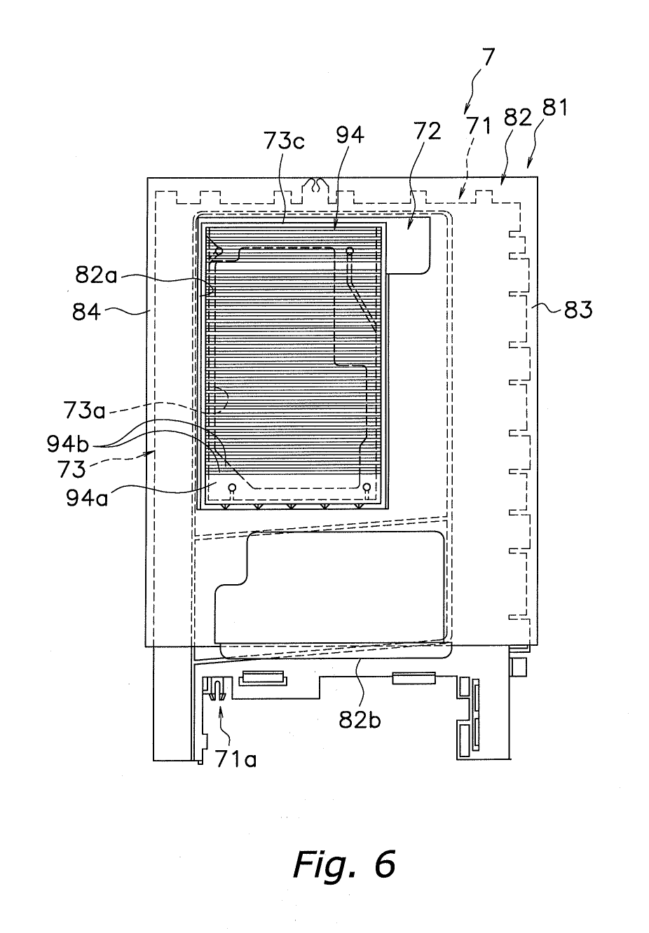

Next, the structure of the electric equipment assembly 7 is described in detail with reference to FIGS. 3 to 6. Here, FIG. 3 is a view of the electric equipment assembly 7 provided in the machine chamber S2, viewed from the bottom. FIG. 4 is a view of the electric equipment assembly 7 provided in the machine chamber S2, viewed in the direction A in FIG. 1. FIG. 5 is a view of the electric equipment assembly 7 provided in the machine chamber S2, viewed in the direction B in FIG. 1. FIG. 6 is a view of the electric equipment assembly 7, with the partition plate 28 removed from FIG. 5.

The frame 71 is a generally rectangular parallelepiped box shaped member made of resin, to which various electric components including the control circuit board 91 mounted with the operating control element and the inverter control element 92 are attached. The frame 71 mainly comprises a substrate attachment plate 72 to which various electric components including the control circuit board 91 and the inverter control element 92 are attached, and a substrate protection plate 76 that covers the control circuit board 91.

The substrate attachment plate 72 is a member disposed on the fan chamber S1 side in the machine chamber S2, with the electric equipment assembly 7 disposed in the machine chamber S2. The substrate attachment plate 72 mainly includes an attachment plate portion 73 as a first plate which is inclined to the front side of the unit casing 2 (i.e., the front side portions of the left and right front plates 23, 24) and which extends vertically, and an attachment frame portion 74 which extends from the outer perimeter of the attachment plate portion 73 toward a side opposite the fan chamber S1. An attachment plate opening 73a is formed generally in the center of the attachment plate portion 73 when the attachment plate portion 73 is seen in the direction of arrow A or arrow B. The surface of the attachment plate portion 73 on the side opposite the fan chamber S1 has an inverter control element 92 attached thereto, at a position facing the attachment plate opening 73a. The inverter control element 92 is, for example, an electric component such as a power transistor, a diode, etc., which generates high temperature heat during operation. In addition, the control circuit board 91 mounted with an operating control element is attached to the surface of the attachment plate portion 73 on the side opposite the fan chamber S1, with the control circuit board 91 in parallel to the surface of the attachment plate portion 73, by using a plurality of screws 93. In other words, as is the case with the attachment plate portion 73, the substrate surface of the control circuit board 91 is inclined to the front side of the unit casing 2 and extends vertically. In this embodiment, the control circuit board 91 is disposed so as to sandwich the inverter control element 92 between the control circuit board 91 and the surface of the attachment plate portion 73 on the side opposite the fan chamber S1, and the control circuit board 91 is integrated with the inverter control element 92. In addition, a heat sink 94 is attached to the surface of the attachment plate portion 73 on the fan chamber S1 side so as to cover the attachment plate opening 73a. The heat sink 94 mainly includes a flange portion 94a attached to the surface of the attachment plate portion 73 on the fan chamber S1 side, and a plurality of horizontal cooling fins 94b that protrude from the surface of the flange portion 94a on the fan chamber S1 side toward the inside of the fan chamber S1. The flange portion 94a is a generally rectangular shaped plate portion. An annular projecting portion 73c that protrudes toward the fan chamber S1 is formed on the surface of the attachment plate portion 73 on the fan chamber S1 side so as to surround the outer perimeter of the flange portion 94a.

The substrate protection plate 76 is a member disposed to the substrate attachment plate 72 on the side opposite the fan chamber S1, with the electric equipment assembly 7 provided in the machine chamber S2. The substrate protection plate 76 mainly includes a protection plate portion 77 which is inclined to the front side of the unit casing 2 (i.e., the front side portions of the left and right front plates 23, 24) and which extends vertically, and a protection frame portion 78 which extends from the outer perimeter of the protection plate portion 77 toward the fan chamber S1 side. With the electric equipment assembly 7 provided in the machine chamber S2, the protection plate portion 77 mainly includes a front side protection plate portion 77a disposed closer to the front side of the unit casing 2, and a rear side protection plate portion 77b disposed further from the front side of the unit casing 2 compared to the front side protection plate portion 77a. The rear side protection plate portion 77b is integrated with the front side protection plate portion 77a, with the rear side protection plate portion 77b protruding in the direction of arrow B compared with the front side protection plate portion 77a, via a step formed generally in the center of the protection plate portion 77 in the horizontal direction, when the protection plate portion 77 is seen in the direction of arrow A. The front side protection plate portion 77a and the rear side protection plate portion 77b are disposed in parallel to the surface of the attachment plate portion 73. The protection frame portion 78 is disposed such that the end portion thereof and the end portion of the attachment frame portion 74 in the direction of arrow A or arrow B overlap with each other, when the protection frame portion 78 is seen in the direction perpendicular to the attachment frame portion 74 in the direction of arrow A or arrow B. The substrate protection plate 76 is attached to the substrate attachment plate 72 by using an engaging claw formed on the protection frame portion 78 or the attachment frame portion 74, screw, or the like. In addition, apart from the control circuit board 91, a first auxiliary circuit board 98 is attached to the outer surface of the front side protection plate portion 77a (i.e. the surface seen when the substrate protection plate 76 is viewed in the direction of arrow A). The first auxiliary circuit board 98 is mounted with a highly frequently accessed control element among various operating control elements, which requires visibility and serviceability (for example, a display element 98a such as an LED and the like, and an operating element 98b such as a switch, connector, and the like). Here, the first auxiliary circuit board 98 is fixed on a first auxiliary circuit board attachment portion 79 including a plurality of (four in this case) locking claws 77c formed on the outer surface of the front side protection plate portion 77a. Further, with the electric equipment assembly 7 disposed in the machine chamber S2, it is possible to attach second auxiliary circuit boards 99a, 99b, and 99c respectively to the lower side of the first auxiliary circuit board attachment portion 79 of the front side protection plate portion 77a, an upper portion of the rear side protection plate portion 77b, and a lower portion of the rear side protection plate portion 77b. Each of the second auxiliary circuit boards 99a, 99b, and 99c is mounted with an additional-function control element, which is an element necessary for adding an additional function (for example, communication function, demand control function, etc.). Here, the second auxiliary circuit board 99a can be fixed on a second auxiliary circuit board attachment portion 80a including a plurality of (four in this case) locking claws 77d formed on the outer surface of the front side protection plate portion 77a. The second auxiliary circuit board 99b can be fixed on a second auxiliary circuit board attachment portion 80b including a plurality of (three in this case) screw holes 77e formed on the outer surface of the rear side protection plate portion 77b. The second auxiliary circuit board 99c can be fixed on a second auxiliary circuit board attachment portion 80c including a plurality of (three in this case) locking claws 77f formed on the outer surface of the rear side protection plate portion 77b. Note that even when the frame 71 (i.e., the substrate protection plate 76) is viewed in the direction of arrow A, the frame 71 is inclined to the front side of the unit casing 2 such that the entirety of the highly frequently accessed control elements 98a, 98b (i.e., the whole first auxiliary circuit board 98) are visible, without being hidden by the lateral sides of the unit casing 2 (i.e., the lateral side portion of the right front plate 24 and the lateral side portion of the right side plate 25). More specifically, when the frame 71 (i.e., the substrate protection plate 76) is viewed in the direction of arrow A, the frame 71 is inclined to the front side of the unit casing 2 such that the front end of the lateral side of the unit casing 2 substantially overlaps with the step extending in an up and down direction of the substrate protection plate 76.

In addition, with the electric equipment assembly 7 provided in the machine chamber S2, a reactor 96 is attached to the upper surface of the frame 71 via a metallic reactor attachment plate 85, and a noise filter 97 is attached to the lower surface of the frame 71.

The frame 71 to which the above described various electric components and the heat sink 94 are attached has a frame support plate 81 that is fixed thereto so as to cover the surface of the attachment plate portion 73 on the fan chamber S1 side. The frame support plate 81 is a metallic member. With the electric equipment assembly 7 provided in the machine chamber S2, the frame support plate 81 mainly includes a support plate portion 82 as a second plate portion in contact with the surface of the attachment plate portion 73 on the fan chamber S1 side, and a front side extension portion 83 and a rear side extension portion 84 which extend along the bent surface of the partition plate 28 from both side edges of the support plate portion 82. Here, the support plate portion 82 covers substantially the entire surface of the attachment plate portion 73 except for the lower portion thereof. The support plate portion 82 has a support plate opening 82a formed therein as a second opening so as to surround the outer peripheral side of the annular projecting portion 73c formed on the attachment plate portion 73. Accordingly, with the frame 71 fixed to the frame support plate 81, the plurality of cooling fins 94b of the heat sink 94 attached to the frame 71 penetrate through the support plate opening 82a and protrude toward the fan chamber S1 side of the support plate portion 82. In addition, the support plate portion 82 has a tongue portion 82b formed thereon by bending and the like, whose lower end extends toward the fan chamber S1 side and then extends downwardly. With the frame 71 fixed to the partition plate 28, the frame support plate 81 is fixed to the partition plate 28 by using, for example, an engaging claw formed on the front side extension portion 83, the rear side extension portion 84, or the support plate portion 82, a screw, or the like. Here, the partition plate 28 has a generally rectangular shaped partition plate opening 28a formed therein as a first opening so as to communicate the fan chamber S1 and the machine chamber S2. The partition plate opening 28a is formed so as to face the support plate opening 82a and to surround the support plate opening 82a and the lower end of the support plate portion 82 when the partition plate opening 28a is viewed in the direction of arrow B. Accordingly, with the frame 71 fixed to the partition plate 28 via the frame support plate 81, the plurality of cooling fins 94b of the heat sink 94 and the tongue portion 82b of the frame support plate 81 protrude into the fan chamber S1 and are capable of cooling the inverter control element 92 during operation. In addition, with the frame 71 disposed in the machine chamber S2, the frame 71 is provided such that the substrate surface of the control circuit board 91 extends along the partition plate 28 and such that the substrate surface of the control circuit board 91 is inclined to the front side of the unit casing 2. Further, a corner of the frame 71 is in contact with the partition plate 28 along a bent surface thereof via a frame support plate 81, when the electric equipment assembly 7 disposed in the machine chamber S2 is viewed from the top.

The terminal block 86 mainly includes a terminal block body 86a having a plurality of terminals for power supply connection, and a terminal block fixing plate 86b to which the rear side of the terminal block body 86a is fixed. With the electric equipment assembly 7 provided in the machine chamber S2, the terminal block 86 is disposed such that a terminal portion of the terminal block body 86a faces the front side of the unit casing 2, and one end of the terminal block fixing plate 86b on the partition plate 28 side is fixed to the partition plate 28. Note that one end of the terminal block fixing plate 86b may be fixed to the front portion of the left front plate 23.

The terminal block support member 87 is a rod shaped member having a first terminal block support portion 87a configured to support the terminal block 86 with the electric equipment assembly 7 provided in the machine chamber S2, and a frame supported portion 87b rotatably supported around an engaging shaft 71a (whose shaft center is O), which is a shaft that extends in an up and down direction of the frame 71 with the electric equipment assembly 7 provided in the machine chamber S2. The terminal block support member 87 is capable of moving the first terminal block support portion 87a closer to or away from the substrate surface of the control circuit board 91, by rotating the frame supported portion 87b. The other end of the terminal block fixing plate 86b is supported by being attached to the first terminal block support portion 87a by setting the terminal block support member 87 to the first state in which the terminal block support member 87 is inclined by an angle α.

In this way, with the electric equipment assembly 7 of this embodiment, the terminal block 86, apart from the frame 71, is fixed to the partition plate 28 so as to face the front side of the unit casing 2, and the terminal block 86 is also supported by the terminal block support member 87 provided to the frame 71.

(6) Characteristics of the Electric Equipment Assembly and the Outdoor Unit Provided with the Same of the Present Embodiment

The electric equipment assembly 7 and the outdoor unit 1 provided with the same as described in the present embodiment have the following characteristics.

### (A)

With the electric equipment assembly 7 and the outdoor unit 1 provided with the same of the present embodiment, the frame 71 is provided in the unit casing 2 such that the substrate surface of the control circuit board 91 is positioned along the partition plate 28 and is also inclined to the front side of the unit casing 2. This structure prevents protrusion of part of the frame 71 into the fan chamber S1. In addition, maintenance and the like of the control circuit board 91 can be easily performed simply by removing the right front plate 24 even when a plurality of outdoor units 1 each provided with this type of electric equipment assembly 7 are juxtaposed to each other. Accordingly, with this electric equipment assembly 7, it is possible to prevent an increase in airflow resistance loss in the fan chamber S1 and ensure on-site workability at the same time.

### (B)

With the electric equipment assembly 7 of the present embodiment, the corner of the frame 71 on the partition plate 28 side is in contact with the bent surface of the partition plate 28, thus the corner of the frame 71 does not protrude into the fan chamber S1. Accordingly, it is possible to reliably prevent an increase in airflow resistance in the fan chamber S1.

### (C)

With the electric equipment assembly 7 of the present embodiment, the highly frequently accessed control elements 98a, 98b are disposed closer to the front side of the unit casing 2, thus it is possible to improve visibility and serviceability of the highly frequently accessed control elements 98a, 98b.

Further, with the electric equipment assembly 7 of the present embodiment, the frame 71 is inclined to the front side of the unit casing 2 such that the entirety of the highly frequently accessed control elements 98a, 98b is visible, without being hidden by the lateral sides of the unit casing 2 even when the electric equipment assembly 7 is viewed in a direction perpendicular to the substrate surface of the control circuit board 91. Accordingly, even when a plurality of outdoor units 1 each provided with this type of electric equipment assembly 7 are juxtaposed to each other, it is possible to maintain visibility and serviceability of the highly frequently accessed control elements 98a, 98b in good condition and further improve on-site workability.

In particular, with the electric equipment assembly 7 of the present embodiment, the first auxiliary circuit board 98 different from the control circuit board 91 and mounted with the highly frequently accessed control elements 98a, 98b is attached on the outer surface of the substrate protection plate 76 that covers the substrate attachment plate 72 from the side opposite the partition plate 28. Accordingly, it is possible to further improve visibility and serviceability of the highly frequently accessed control elements.

### (7) Alternative Embodiment

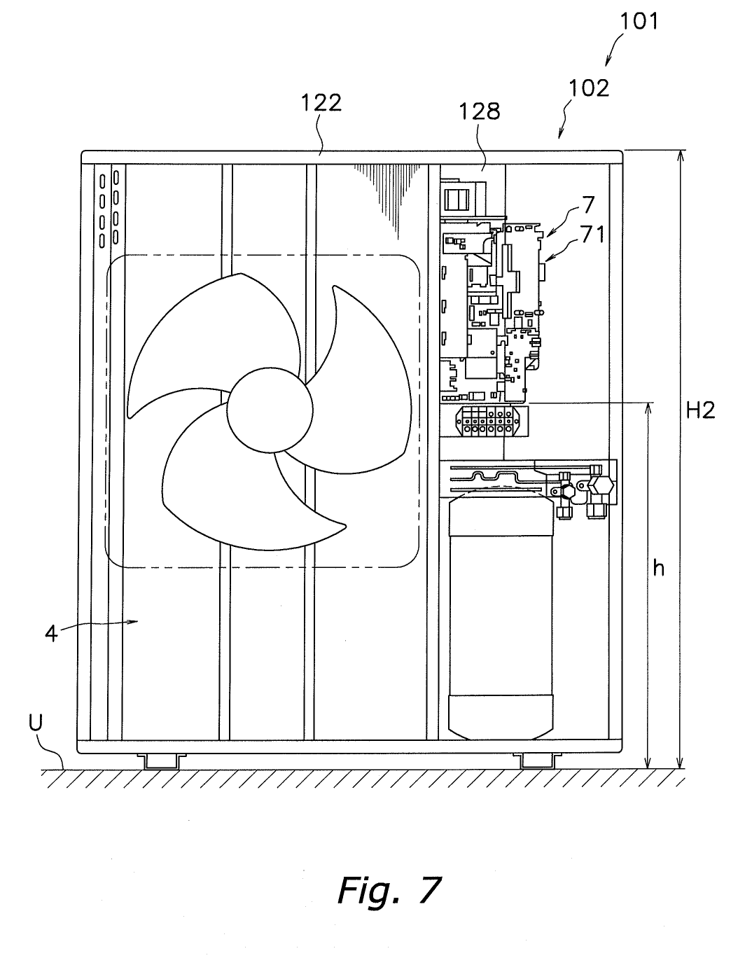

The above described embodiment is explained using an example in which the present invention is applied to the outdoor unit 1 having the two outdoor fans 4 disposed above and below in the unit casing 2. However, the present invention may be applied to an outdoor unit 101 having only one outdoor fan 4 disposed in a unit casing 102 (see FIG. 7). In this case, an overall height H2 of the unit casing 102 of the outdoor unit 101 above the installation surface U is lower than the overall height H1 (see FIG. 2) of the unit casing 2 of the outdoor unit 1. However, the installation height of the frame 71 of the electric equipment assembly 7 in this outdoor unit 101 is configured to be equal to the installation height h of the frame 71 of the electric equipment assembly 7 (for example, the lower end of the frame 71 is used as a measurement basis) disposed in the unit casing 2 of the outdoor unit 1, by using the electric equipment assembly 7 in the outdoor unit 1, which is the same electric equipment assembly 7 used in the outdoor unit 101, and by placing this electric equipment assembly 7 immediately below a top plate 122 of the unit casing 102. In other words, when installing the electric equipment assembly 7 in the outdoor unit 1, a locking claw, a screw hole, and the like for fixing the electric equipment assembly 7 to the unit casing 2 and the partition plate 28 are provided so as to install the electric equipment assembly 7 with a wide clearance between the top plate 22 of the unit casing 2 and the frame 71; whereas when installing the electric equipment assembly 7 in the outdoor unit 101, a locking claw, a screw hole, and the like for fixing the electric equipment assembly 7 to the unit casing 102 and the partition plate 128 are provided so as to install the electric equipment assembly 7 with a narrow clearance between the top plate 122 of the unit casing 102 and the frame 71.

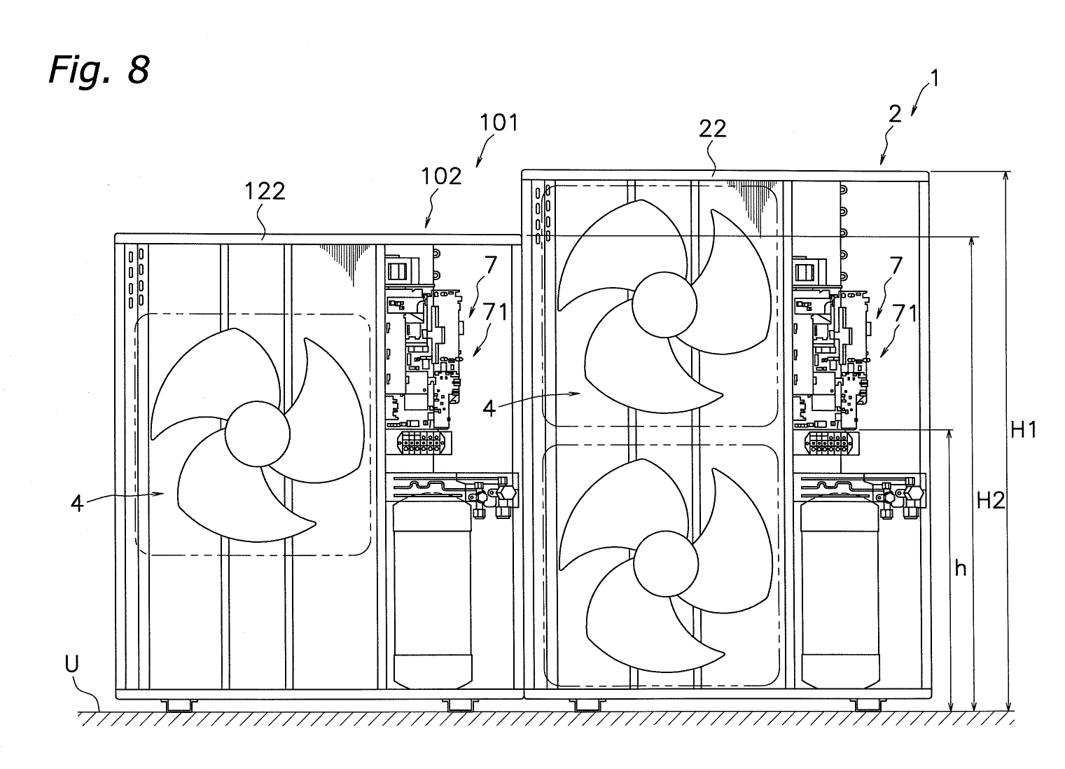

Accordingly, as shown in FIG. 8, in the air conditioner in which the outdoor unit 101 is laterally juxtaposed to the outdoor unit 1, the frame 71 is disposed in each of the casings 2 and 102 such that the frame 71 of the electric equipment assembly 7 in each of the casing 2 and 102 has the same installation height h (for example, the lower end of the frame 71 is used as a measurement basis), even though the overall height of the unit casing 2 of the outdoor unit 1 is different from that of the unit casing 102 of the outdoor unit 101. Therefore, as in the case with the above described embodiment, maintenance and the like of the control circuit board 91 can be easily performed, and operators will have access to each electric equipment assembly 7 in the same position. Accordingly, even when a plurality of outdoor units 1, 101 respectively having the casings 2, 102 with different heights are laterally juxtaposed to each other, it is possible to improve on-site workability.

### INDUSTRIAL APPLICABILITY

With the utilization of the present invention, in an outdoor unit of an air conditioner having a structure in which the inside of a casing having a generally rectangular parallelepiped box shape is divided into a fan chamber and a machine chamber by a partition plate extending vertically, it is possible to prevent an increase in airflow resistance in the fan chamber and ensure on-site workability at the same time.

1. An electric equipment assembly sized and configured to be disposed in a machine chamber of an outdoor unit of an air conditioner having a structure in which an inside of a casing having a generally rectangular parallelepiped box shape is divided into a fan chamber and the machine chamber by a partition plate extending vertically, the electric equipment assembly comprising:
a frame; and
a plurality of electric components attached to the frame, the electric components including a control circuit board with operating control elements and an inverter control element,
the frame being disposed such that a substrate surface of the control circuit board is positioned along the partition plate and is also inclined relative to a front side of the casing when the frame is disposed in the machine chamber of in the casing.

2. The electric equipment assembly according to claim 1, wherein
the frame has a generally rectangular shape as viewed along a plan view of the casing when the frame is disposed in the machine chamber of the casing, and
a corner of the frame on a partition plate side is in contact with the partition plate so as to be positioned along a bent surface of the partition plate when the frame is disposed in the machine chamber of the casing.

3. The electric equipment assembly according to claim 1, wherein
the operating control elements include a frequently accessed control element disposed closer to the front side of the casing when the frame is disposed in the machine chamber of the casing.

4. The electric equipment assembly according to claim 3, wherein
the frame is inclined relative to the front side of the casing when the frame is disposed in the machine chamber of the casing such that an entirety of the frequently accessed control element is visible without being hidden by a lateral side of the casing even when the frame is viewed in a direction perpendicular to the substrate surface when the frame is disposed in the machine chamber of the casing.

5. The electric equipment assembly according to claim 3, wherein
the frame includes a substrate attachment plate disposed along the partition plate and a substrate protection plate configured to cover the substrate attachment plate from a side opposite the partition plate when the frame is disposed in the machine chamber of the casing, and
the substrate protection plate has an auxiliary circuit board attached to an outer surface thereof, the auxiliary circuit board being different from the control circuit board and mounted with the frequently accessed control element.

6. An outdoor unit of an air conditioner comprising:
a casing having a generally rectangular parallelepiped box shape;
a partition plate extending vertically so as to divide an inside of the casing into a fan chamber and a machine chamber; and
an electric equipment assembly, disposed in the machine chamber of the casing, the electric equipment assembly including
a frame, and
a plurality of electric components attached to the frame, the electric components including a control circuit board with operating control elements and an inverter control element,
the frame being disposed such that a substrate surface of the control circuit board is positioned along the partition plate and is also inclined relative to a front side of the casing.

7. An air conditioner including a pair of the outdoor units according to claim 6 as a first and second outdoor units juxtaposed relative to each other wherein
the casing of the second outdoor unit has a different height from the casing of the first outdoor unit, and the frame of the electric equipment assembly of the first outdoor unit and the frame of the electric equipment assembly of the second outdoor unit are disposed at the same height from an installation surface of each casing.

8. The air conditioner according to claim 7, wherein
each frame has a generally rectangular shape as viewed along a plan view of the respective casing in which it is disposed in the machine chamber of the casing, and
a corner of each frame on a partition plate side is in contact with the partition plate so as to be positioned along a bent surface of the partition plate.

9. The air conditioner according to claim 7, wherein
the operating control elements of each electric equipment assembly include a frequently accessed control element disposed closer to the front side of the respective casing in which the respective electric equipment assembly is disposed.

10. The air conditioner according to claim 9, wherein
each frame is inclined relative to the front side of the respective casing in which the respective electric equipment assembly is disposed such that an entirety of each of the frequently accessed control elements is visible without being hidden by a lateral side of the casing in which the respective electric equipment assembly is disposed even when the frame is viewed in a direction perpendicular to the substrate surface.

11. The air conditioner according to claim 9, wherein
each frame includes a substrate attachment plate disposed along the respective partition plate and a substrate protection plate configured to cover the substrate attachment plate from a side opposite the partition plate of the casing in which the respective electric equipment assembly is disposed, and
each substrate protection plate has an auxiliary circuit board attached to an outer surface thereof, the auxiliary circuit boards being different from the control circuit boards and mounted with the frequently accessed control elements.

12. The outdoor unit according to claim 6, wherein
the frame has a generally rectangular shape as viewed along a plan view of the casing, and
a corner of the frame on a partition plate side is in contact with the partition plate so as to be positioned along a bent surface of the partition plate.

13. The outdoor unit according to claim 6, wherein
the operating control elements include a frequently accessed control element disposed closer to the front side of the casing.

14. The outdoor unit according to claim 13, wherein
the frame is inclined relative to the front side of the casing such that an entirety of the frequently accessed control element is visible without being hidden by a lateral side of the casing even when the frame is viewed in a direction perpendicular to the substrate surface.

15. The outdoor unit according to claim 13, wherein
the frame includes a substrate attachment plate disposed along the partition plate and a substrate protection plate configured to cover the substrate attachment plate from a side opposite the partition plate, and
the substrate protection plate has an auxiliary circuit board attached to an outer surface thereof, the auxiliary circuit board being different from the control circuit board and mounted with the frequently accessed control element.
